(19) United States
(12) Patent Application Publication
(10) Pub. No.: US 2026/0121596 A1
(43) Pub. Date: Apr. 30, 2026

(54) SEMICONDUCTOR DEVICE AND INTEGRATED CIRCUIT

(71) Applicant: Hitachi, Ltd., Tokyo (JP)

(72) Inventors: Masahiro MASUNAGA, Tokyo (JP); Shinji NOMOTO, Tokyo (JP); Ryo KUWANA, Tokyo (JP); Akio SHIMA, Tokyo (JP); Isao HARA, Tokyo (JP)

(21) Appl. No.: 19/303,605

(22) Filed: Aug. 19, 2025

(30) Foreign Application Priority Data
Oct. 25, 2024 (JP) 2024-188284

(51) Int. Cl. H01L 21/04; H03F 3/16; H10D 62/832; H10D 84/01; H10D 84/03; H10D 84/85

(52) U.S. Cl. CPC H03F 3/16; H10D 62/8325; H10D 84/017; H10D 84/0191; H10D 84/035; H10D 84/858

(57) ABSTRACT

The present invention provides a semiconductor device capable of reducing the offset drift of an amplifier which is caused by the NBTI of a p-channel MOS transistor. The semiconductor device includes: an n-channel MOS transistor formed on a main surface of a substrate using silicon carbide, and a p-channel MOS transistor formed on a main surface of a substrate using silicon carbide. Each of the n-channel MOS transistor and the p-channel MOS transistor has, on the main surface of the substrate, a gate electrode via a gate oxide film, and a dangling bond is terminated, at an interface between the substrate and the gate oxide film, by an element added, and a concentration of the element with which the dangling bond is terminated in the p-channel MOS transistor is smaller than that with which the dangling bond is terminated in the n-channel MOS transistor.

### CROSS-REFERENCE TO RELATED APPLICATION

The present application claims priority from Japanese application JP2024-188284, filed on Oct. 25, 2024, the content of which is hereby incorporated by reference into this application.

### BACKGROUND

The present invention relates to a semiconductor device having a substrate made of SiC (silicon carbide) and an integrated circuit provided with the semiconductor device.

General-purpose devices using silicon cannot be used in products used under high-temperature circumstances and when the products are provided with a cooling device to solve this problem, reduction in the size and weight or the cost of the products cannot be achieved easily.

As a device that can operate at high temperatures, on the other hand, there is a semiconductor device (for example, refer to Japanese Unexamined Patent Application Publication No. 2019-12780) having a substrate made of SiC (silicon carbide).

In addition, in particular, nuclear instrumentation devices including pressure transmitters are required to have improved radiation resistance. Using an SiC amplifier for nuclear instrumentation devices contributes to further improvement in the safety of a nuclear power plant because it no longer requires a shielding wall.

### SUMMARY

The SiC amplifier is comprised of a plurality of n-channel MOS transistors and p-channel MOS transistors. These n-channel MOS transistors and p-channel MOS transistors have a structure in which a thin gate oxide film is formed on an SiC epitaxial layer and a drain current flows through an SiC/SiO₂ interface.

This SiC/SiO₂ interface is annealed, for example, with NO (nitrogen oxide) in order to reduce interfacial defects.

Annealing with NO however may deteriorate the NBTI (Negative Bias Temperature Instability) characteristics of a p channel MOS transistor because nitrogen induces defects on the valence band side. Deterioration in NBTI characteristics increases the offset drift of the SiC amplifier.

The inventors of the present invention on the other hand have confirmed that the p-channel MOS transistor not subjected to annealing with NO hardly works.

Therefore, it is impossible to manufacture products that use an SiC amplifier without annealing a p-channel MOS transistor with NO.

With a view to overcoming the aforesaid problem, the present invention provides a semiconductor device capable of reducing the offset drift of an amplifier which is caused by the NBTI of a p-channel MOS transistor, and an integrated circuit provided with the semiconductor device.

The aforesaid object, another object, and novel features of the present invention will be made clear by the description herein and attached drawings.

The semiconductor device of the present invention includes: an n-channel MOS transistor formed on a main surface of a substrate using silicon carbide, and a p-channel MOS transistor formed on a main surface of a substrate using silicon carbide. Each of the n-channel MOS transistor and the p-channel MOS transistor has, on the main surface of the substrate, a gate electrode via a gate oxide film, and a dangling bond is terminated, at an interface between the substrate and the gate oxide film, by an element added. Further, in the semiconductor device of the present invention, concentration of the element with which the dangling bond is terminated in the p-channel MOS transistor is smaller than that with which the dangling bond is terminated in the n-channel MOS transistor.

The Integrated circuit of the present invention is equipped with a semiconductor device having a plurality of n-channel MOS transistors formed on the main surface of a substrate using silicon carbide and a plurality of p-channel MOS transistors formed on the main surface of a substrate using silicon carbide.

The integrated circuit of the present invention has a plurality of n-channel MOS transistors and a plurality of p-channel MOS transistors. These n-channel MOS transistors and p-channel MOS transistors have, on the main surface of the substrates, a gate electrode via a gate oxide film. At the same time, the dangling bond is terminated by the addition of an element at the interface between the substrate and the gate oxide film.

Further, in the semiconductor device of the present invention, the concentration of the element with which the dangling bond in the p-channel MOS transistors is terminated is smaller than the concentration of the element with which the dangling bond in the n-channel MOS transistors is terminated.

According to the aforesaid semiconductor device of the present invention and the integrated circuit of the present invention, the concentration of the element with which the dangling bond in the p-channel MOS transistors is terminated is smaller than the concentration of the element with which the dangling bond in the n-channel MOS transistors is terminated.

This makes it possible to reduce the interfacial defects due to an element (nitrogen or the like) with which the dangling bond is terminated and thereby suppress the NBTI. When the NBTI can be suppressed, the offset drift of an SiC amplifier can be reduced.

Objects, configurations, and effects other than the above will be apparent from the description of the following embodiments.

### BRIEF DESCRIPTION OF THE DRAWINGS

FIG. 1 is a schematic block diagram (cross-sectional view) of a semiconductor device of First Embodiment of the present invention.

FIG. 2 is a cross-sectional view for describing a method of manufacturing the semiconductor device of FIG. 1.

FIG. 3 is a cross-sectional view for describing the method of manufacturing the semiconductor device of FIG. 1.

FIG. 4 is a cross-sectional view for describing the method of manufacturing the semiconductor device of FIG. 1.

FIG. 5 is a cross-sectional view for describing the method of manufacturing the semiconductor device of FIG. 1.

FIG. 6 is a cross-sectional view for describing the method of manufacturing the semiconductor device of FIG. 1.

FIG. 7 is a cross-sectional view t for describing the method of manufacturing the semiconductor device of FIG. 1.

FIG. 8 is a cross-sectional view for describing the method of manufacturing the semiconductor device of FIG. 1.

FIG. 9 is a cross-sectional view for describing the method of manufacturing the semiconductor device of FIG. 1.

FIG. 10 shows one example of the nitrogen concentration distribution, in the depth direction, of the n-channel MOS transistor and the p-channel MOS transistor according to First Embodiment of the present invention.

FIG. 11 shows another example of the nitrogen concentration distribution, in the depth direction, of the n-channel MOS transistor and the p-channel MOS transistor according to First Embodiment of the present invention.

FIG. 12 is a schematic block diagram (cross-sectional view) of a semiconductor device of Second Embodiment of the present invention.

FIG. 13 is a schematic block diagram (cross-sectional view) of a semiconductor device of Third Embodiment of the present invention.

FIG. 14 is a view for describing the effect of the present invention in a p-channel MOS transistor.

FIG. 15 is a schematic block diagram (plan view) of an integrated circuit of Fourth Embodiment of the present invention.

FIG. 16 is a schematic block diagram (circuit diagram) of an integrated circuit of Fifth Embodiment of the present invention.

FIG. 17 is a schematic block diagram (plan view) of an integrated circuit of Sixth Embodiment of the present invention.

### DETAILED DESCRIPTION

The embodiments and examples according to the present invention will hereinafter be described using sentences or drawings. The structures, materials, and other specific various constitutions shown in the present invention are not limited to or by the embodiments and examples described herein and they can be combined or improved as needed without changing the gist. The elements having no direct relation with the present invention are omitted from the drawings.

The semiconductor device of the present invention has an n-channel MOS transistor formed on the main surface of a substrate using silicon carbide and p-channel MOS transistors formed on the main surface of a substrate using silicon carbide. Each of the n-channel MOS transistor and the p-channel MOS transistor has, on the main surface of the substrate, a gate electrode via a gate oxide film and at the same time, the dangling bond is terminated by the addition of an element at the interface between the substrate and the gate oxide film.

Further, in the semiconductor device of the present invention, the concentration of an element with which a dangling bond in the p-channel MOS transistor is terminated is smaller than the concentration of an element with which a dangling bond in the n-channel MOS transistor is terminated.

The Integrated circuit of the present invention is equipped with a semiconductor device having a plurality of n-channel MOS transistors formed on the main surface of a substrate using silicon carbide and a plurality of p-channel MOS transistors formed on the main surface of a substrate using silicon carbide.

The integrated circuit of the present invention has a plurality of n-channel MOS transistors and a plurality of p-channel MOS transistors. These n-channel MOS transistors and p-channel MOS transistors have, on the main surface of the substrates, a gate electrode via a gate oxide film. At the same time, the dangling bond is terminated by the addition of an element at the interface between the substrate and the gate oxide film.

Further, in the semiconductor device of the present invention, the concentration of the element with which the dangling bond in the p-channel MOS transistors is terminated is smaller than the concentration of the element with which the dangling bond in the n-channel MOS transistors is terminated.

In short, the integrated circuit of the present invention is an integrated circuit which is provided with a semiconductor device having a plurality of n-channel MOS transistors formed on the main surface of a substrate using silicon carbide and a plurality of p-channel MOS transistors formed on the main surface of a substrate using silicon carbide and applies, as the semiconductor device, the aforesaid semiconductor device of the present invention.

According to the semiconductor device and the integrated circuit of the present invention, the concentration of an element with which the dangling bond in the p-channel MOS transistor is terminated is smaller than the concentration of an element with which the dangling bond in the n-channel MOS transistor is terminated.

This makes it possible to reduce the interfacial defects due to an element (nitrogen or the like) with which the dangling bond is terminated and thereby suppress the NBTI. When the NBTI can be suppressed, the offset drift of an SiC amplifier can be reduced.

Reduction in interfacial defects is also effective for reducing low-frequency noise and this makes it possible to reduce the unsteadiness of the output of the amplifier at DC (direct current).

The aforesaid semiconductor device can have the constitution in which the p-channel MOS transistor is smaller than the n-channel MOS transistor in the maximum concentration in the concentration distribution of an element with which the dangling bond is terminated.

According to the constitution described above, since the maximum concentration in the concentration distribution of an element in the p-channel MOS transistor is small, the concentration of the element can be made smaller.

The aforesaid semiconductor device can have the constitution in which the p-channel MOS transistor is smaller than the n-channel MOS transistor in the integration value of the concentration in the concentration distribution of an element with which the dangling bond is terminated.

Since the integration value of the concentration in the concentration distribution of an element is proportional to the introduction amount of the element, it can be estimated from the introduction amount of the element. This means that a reduction in the integration value of the concentration in the concentration distribution of the element can be achieved by a reduction in the introduction amount of the element.

In the aforesaid constitution, the integration value of the concentration in the concentration distribution of the element in the p-channel MOS transistor is small, making it possible to make the concentration of the element smaller.

The aforesaid semiconductor device can have the constitution in which the gate oxide film of the p-channel MOS transistor has a smaller thickness than that of the n-channel MOS transistor.

Since in the aforesaid constitution, the gate oxide film of the p-channel MOS transistor is thinner than that of the n-channel MOS transistor, this constitution can enhance the effect of suppressing NBTI, reducing the offset drift of the SiC amplifier, and reducing the unsteadiness of the output of the amplifier at DC (direct current).

The aforesaid semiconductor device can have a constitution in which the substrate used for having thereon the n-channel MOS transistor and the substrate used for having thereon the p-channel MOS transistor are the same.

Such a constitution can reduce the number of the substrates because only one substrate is necessary therefor.

The aforesaid semiconductor device may have a constitution in which the substrate used for having thereon the n-channel MOS transistor and the substrate used for having thereon the p-channel MOS transistor are respectively different ones.

Since in this constitution, the substrate used for having thereon the n-channel MOS transistor and the substrate used for having thereon the p-channel MOS transistor are respectively different ones, it is possible to reduce the number of the formation times of a resist or the like used as a mask in manufacturing a semiconductor device having such a constitution, and thereby simplify the manufacturing steps.

The aforesaid integrated circuit can have a constitution in which a plurality of n-channel MOS transistors is formed on a first substrate and a plurality of p-channel MOS transistors is formed on a second substrate different from the first substrate.

In this constitution, the first substrate used for forming the n-channel MOS transistors thereon and the second substrate used for forming the p-channel MOS transistors thereon are respectively different ones. In manufacturing an integrated circuit having such a constitution, it is possible to reduce the number of formation times of a resist or the like used as a mask and thereby simplify the manufacturing steps.

The aforesaid integrated circuit may further have a constitution in which it further has a differential circuit and the differential circuit or a portion of the differential circuit is formed on the same substrate as that of a plurality of n-channel MOS transistors and/or a plurality of p-channel MOS transistors.

In this constitution, since the plurality of n-channel MOS transistors and/or the plurality of p-channel MOS transistors, and the differential circuit are formed on the same substrate, the n-channel MOS transistors and/or the p-channel MOS transistors which are formed on the same substrate as that of the differential circuit can be made to have similar properties. By the aforesaid constitution, therefore, the offset drift of the differential circuit can be suppressed.

The aforesaid integrated circuit can have a constitution in which a plurality of n-channel MOS transistors and a plurality of p-channel MOS transistors are formed on the same substrate.

According to this constitution, since the n-channel MOS transistors and the p-channel MOS transistors are formed on the same substrate, a constitution for connecting between substrates becomes unnecessary, the number of parts such as electrode pad and metal wire can be reduced, and therefore, the degree of freedom in designing the layout of the integrated circuit can be enhanced.

The semiconductor device and the integrated circuit according to the present invention can be applied to various products using a semiconductor device.

Particularly, nuclear instrumentation devices, such as pressure transmitters, to which the aforesaid semiconductor device or integrated circuit is applied, can have excellent radiation resistance and improved safety because the semiconductor device and integrated circuit are each comprised of a substrate using silicon carbide.

In addition, application of the semiconductor device or the integrated circuit of the present invention makes it possible to suppress NBTI and thereby reduce the offset drift of an SiC amplifier. Further, it can reduce the low-frequency noise and thereby reduce the unsteadiness of the output of the amplifier at DC (direct current).

The nuclear implementation devices can be applied to various devices in a nuclear power plant, for example, decommissioning robots or radiation-using devices.

In the semiconductor device and integrated circuit, examples of an element with which a dangling bond is terminated at the interface between the substrate and the gate oxide film of the n-channel MOS transistors and p-channel MOS transistors include nitrogen (N), hydrogen (H), and phosphorus (P).

Examples of a gas to be fed to terminate a dangling bond with nitrogen include NO, N₂O, and NH₃.

Examples of a gas to be fed to terminate a dangling bond with hydrogen include H₂ (hydrogen gas).

Examples of a gas to be fed to terminate a dangling bond with phosphorus include POCl (phosphoryl chloride).

Particularly when a dangling bond is terminated with nitrogen, a production cost can be reduced by using a nitrogen compound which is available at a relatively low cost.

In the aforesaid semiconductor device and integrated circuit, the concentration of an element with which a dangling bond is terminated is made smaller in the p-channel MOS transistors than in the n-channel MOS transistors.

Such a constitution can be manufactured by setting a temperature lower and/or setting an implantation time shorter when the p-channel MOS transistors are implanted with an element (nitrogen, hydrogen, phosphorus, or the like) with which a dangling bond is terminated than when the n-channel MOS transistors are implanted.

A specific amount in setting a temperature lower or setting an implantation time shorter is such an amount that causes at least a significant difference in the concentration of the used element. When there is a desired concentration of the used element of the p-channel MOS transistors, the amount is set to correspond to the concentration.

The effect of the present invention will hereinafter be described in further detail.

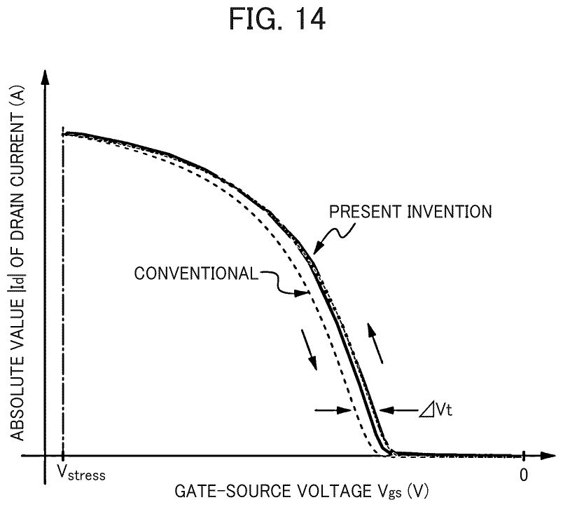

A view for describing the effect of the present invention in the p-channel MOS transistors is shown in FIG. 14.

FIG. 14 shows, in the conventional constitution and the constitution of the present invention, a change in absolute value |I_{d}| of a drain current, that is, I_{d}-V_{gs} characteristics when a gate-source voltage V_{gs} is swept from 0 V to Vₛₜᵣₑₛₛ and then swept from Vₛₜᵣₑₛₛ to 0 V.

The I_{d}-V_{gs} characteristics shown in FIG. 14 are measurement results obtained under the conditions of a room temperature and a drain-source voltage |V_{ds}| of 50 mV. In FIG. 14, the results of the constitution of the present invention are indicated by a solid line and the results of the conventional constitution are indicated by a broken line.

In the conventional constitution, the nitrogen concentration at the interface of a channel portion of the p-channel MOS transistors is set to optimize the characteristics of the n-channel MOS transistors. This means that in the conventional constitution, the nitrogen concentration at the interface of a channel portion of the p-channel MOS transistors is set equal to the nitrogen concentration at the interface of a channel portion of the n-channel MOS transistors.

As is apparent from FIG. 14, in the conventional constitution, the shift amount ΔVₜ of a threshold voltage is large.

In the constitution of the present invention, on the other hand, the nitrogen concentration at the interface of a channel portion of the p-channel MOS transistors is set smaller than the nitrogen concentration at the interface of a channel portion of the n-channel MOS transistors.

As is apparent from FIG. 14, the shift amount ΔVₜ of a threshold voltage in the constitution of the present invention is reduced largely.

By using the constitution of the present invention, the shift amount ΔVₜ of a threshold voltage is reduced largely as can be seen from FIG. 14. This makes it possible to reduce the offset drift of an SiC amplifier and the semiconductor device or integrated circuit can have improved stability.

The specific embodiments of the semiconductor device and the integrated circuit according to the present invention will hereinafter be described referring to some drawings.

### First Embodiment

First, a semiconductor device of First Embodiment of the present invention is described.

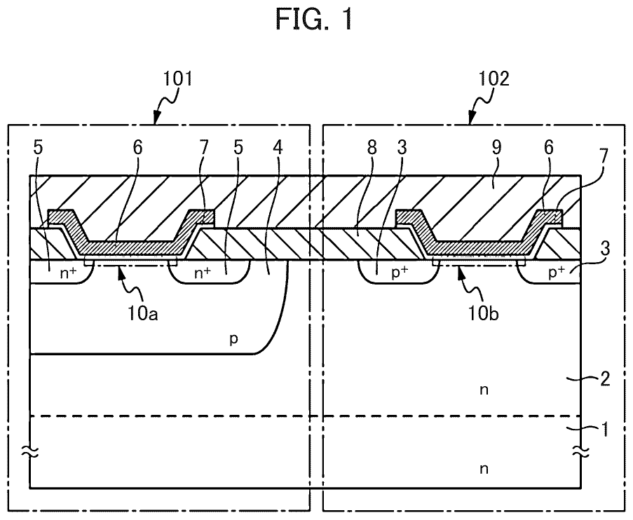

A schematic block diagram (cross-sectional view) of the semiconductor device of First Embodiment of the present invention is shown in FIG. 1.

The semiconductor device shown in FIG. 1 is constituted using an n type SiC substrate 1 which is a semiconductor substrate made of SiC (silicon carbide).

Described specifically, the semiconductor device shown in FIG. 1 has an n-channel MOS transistor 101 and a p-channel MOS transistor 102 on an n type SiC epitaxial layer 2 formed on an n type SiC substrate 1.

In the n-channel MOS transistor 101, an n type high concentration layer 5 is formed on the surface portion of a p type well 4 formed on the n type SiC epitaxial layer 2. In the n-channel MOS transistor 101, a gate electrode 6 made of polysilicon is formed on the p type well layer 4 via a gate oxide film 7.

In the p-channel MOS transistor 102, a p type high concentration layer 3 is formed on the surface portion of the n type SiC epitaxial layer 2. In the p-channel MOS transistor 102, a gate electrode 6 made of polysilicon is formed on the n type SiC epitaxial layer 2 via a gate oxide film 7.

The n-channel MOS transistor 101 and the p-channel MOS transistor 102 are insulated by a thick oxide film layer 8 formed on the n-type SiC epitaxial layer 2 and a passivation layer 9 which is formed to cover the whole surface.

A region 10a which includes a portion to be a channel of the n-channel MOS transistor 101 and is in the vicinity of an interface between the p well layer 4 and the gate oxide film 7 is implanted with nitrogen and is therefore passivated to terminate a dangling bond.

Similarly, a region 10b which includes a portion to be a channel of the p-channel MOS transistor 102 and is in the vicinity of an interface between the n type SiC epitaxial layer 2 and the gate oxide film 7 is implanted with nitrogen and is therefore passivated to terminate a dangling bond.

In the semiconductor device of the present embodiment, the concentration of nitrogen with which the interface between the gate oxide film 7 and an SiC layer is implanted to terminate a dangling bond is different particularly between the region 10a of the n-channel MOS transistor 101 and the region 10b of the p channel MOS transistor 102.

In other words, the concentration of nitrogen with which the interface between the gate oxide film 7 and an SiC layer is implanted in the region 10b of the p-channel MOS transistor 102 is smaller than that in the region 10a of the n-channel MOS transistor 101.

According to the semiconductor device of the present embodiment, the nitrogen concentration in the region 10b of the p-channel MOS transistor 102 is smaller than that in the region 10a of the n-channel MOS transistor 101.

This makes it possible to reduce the interfacial defects caused by nitrogen and suppress NBTI in the p-channel MOS transistor. When the NBTI can be suppressed, the offset drift of an SiC amplifier can be reduced.

In addition, reduction in the interfacial defects is also effective for reducing the low-frequency noise, making it possible to reduce the unsteadiness of the output of an amplifier at DC (direct current).

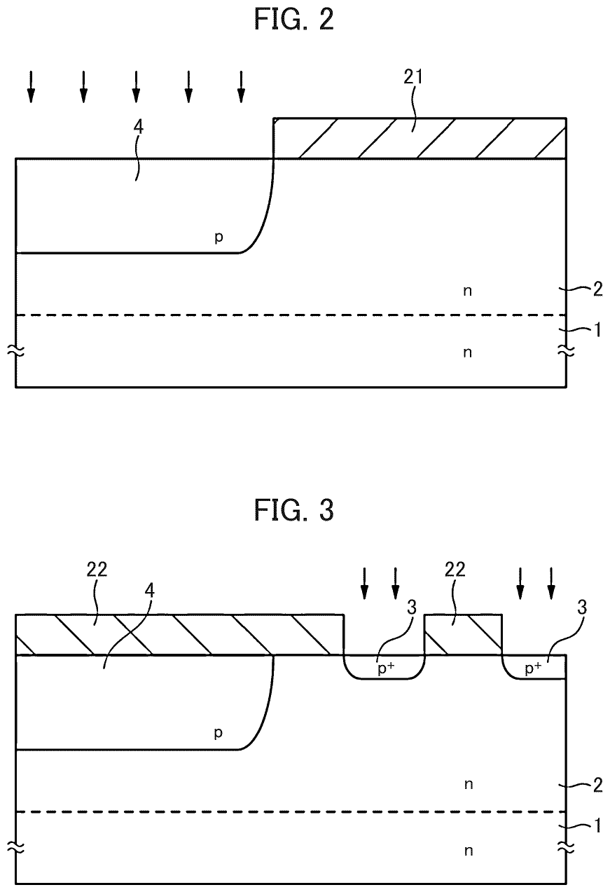

Next, the method of manufacturing the semiconductor device according to the present embodiment will be described referring to the cross-sectional views in FIGS. 2 to 9.

First, an n type SiC epitaxial layer 2 is formed by causing epitaxial growth of an SiC layer on an n type SiC substrate 1. The n type SiC epitaxial layer 2 having a desired impurity concentration can be formed by causing epitaxial growth while introducing an n type impurity (for example, N) if necessary.

Next, a resist 21 is formed on the n-type SiC epitaxial layer 2. Then, the resist 21 is patterned to remove a portion of the resist 21 on a portion corresponding to the p type well layer 4 of the n type SiC epitaxial layer 2.

Next, as shown in FIG. 2, with the resulting resist 21 as a mask, ion implantation of a p type impurity (for example, Al) is performed on the n type SiC epitaxial layer 2 formed on the n type SiC substrate 1 to form a p type well layer 4.

Then, the resist 21 is removed and a resist 22 is formed on the n type SiC epitaxial layer 2. Then, the resist 22 is patterned to remove the resist 22 on a portion of the n type SiC epitaxial layer 2 to be an n type high concentration layer 5.

Next, as shown in FIG. 3, with the resulting resist 22 as a mask, ion implantation of a p type impurity (for example, Al) is performed into a surface portion of the n type SiC epitaxial layer 2 to form a p type high concentration layer 3.

The p type high concentration layer 3 is formed to have an impurity concentration higher than that of the p type well layer 4.

Then, the resist 22 is removed and a resist 23 is formed on the n type SiC epitaxial layer 2. The resist 23 is patterned to remove a portion of the resist 23 on a portion of the p type well layer 4 to be an n type high concentration layer 5.

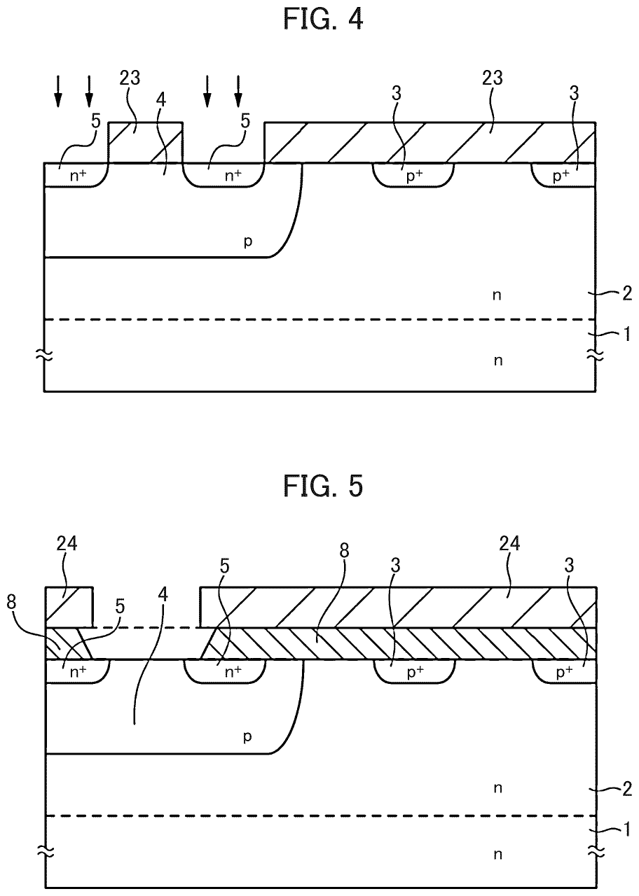

Next, as shown in FIG. 4, with the resulting resist 23 as a mask, ion implantation of an n type impurity (for example, N) is performed into a surface portion of the p type well layer 4 to form an n type high concentration layer 5.

Then, the resist 23 is removed and after formation of an oxide film layer 8 on the n type SiC epitaxial layer 2, a resist 24 is formed. The resist 24 is then patterned.

Next, as shown in FIG. 5, etching is performed with the resulting resist 24 as a mask and a thick oxide film layer 8 on a region including a portion, which will be a channel, between the n type high concentration layers 5 is removed to form an opening.

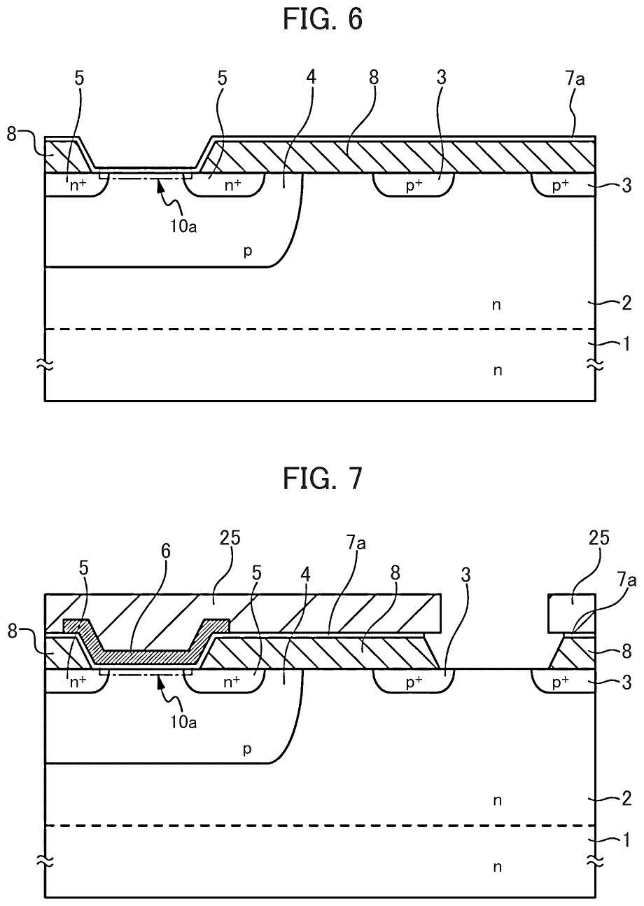

Then, the resist 24 is removed and as shown in FIG. 6, a gate oxide film 7a is formed to cover the surface.

Further, as shown in FIG. 6, passivation by NO annealing is given to the region 10a which includes a portion to be a channel of the n-channel MOS transistor 101 and is in the vicinity of the interface between the p type well layer 4 and the gate oxide film 7.

Next, a polysilicon layer is formed on the gate oxide film 7a, followed by patterning of the polysilicon layer to form a gate electrode 6 of the n-channel MOS transistor 101.

Then, the surface is covered to form a resist 25 and the resulting resist 25 is patterned.

As shown in FIG. 7, with the resist 25 as a mask, etching is performed to remove the gate oxide film 7a and the oxide film layer 8 on a region including a portion to be a channel between the p type high concentration layers 3 and thereby form an opening.

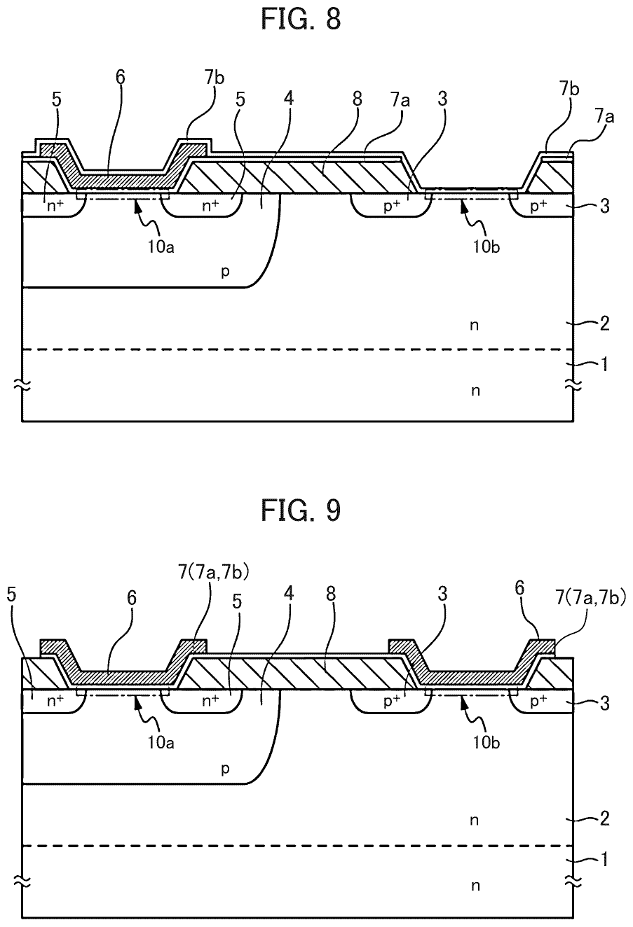

Then, the resist 25 is removed and as shown in FIG. 8, the surface is covered to form a gate oxide film 7b.

Further, as shown in FIG. 8, a region 10b which includes a portion to be a channel of the p-channel MOS transistor 102 and is in the vicinity of the interface between the n type SiC epitaxial layer 2 and the gate oxide film 7b is subjected to passivation by NO annealing.

The nitrogen concentration of NO annealing at this time is made smaller than the nitrogen concentration of NO annealing given to the portion to be a channel of the n-channel MOS transistor 101 shown in FIG. 6.

Then, the surface is covered to form a polysilicon layer, followed by patterning of the polysilicon layer to form a gate electrode 6 of the p-channel MOS transistor 102. With this gate electrode 6 of the p-channel MOS transistor 102 as a mask, etching is performed to remove the gate oxide film 7b and the gate oxide film 7a.

As a result, a gate oxide film 7 comprised of the gate oxide film 7b and the gate oxide film 7a remains under the gate electrode 6 of the p-channel MOS transistor 102 as shown in FIG. 9.

Then, a passivation layer 9 is formed to cover the whole surface. In such a manner, the semiconductor device of the present embodiment shown in FIG. 1 can be manufactured.

In the present embodiment, the nitrogen concentration of a portion including the channel of the p-channel MOS transistor 102 is made smaller than that of a portion including the channel of the n-channel MOS transistor 101. There are presumed to be several constitutions different in nitrogen concentration. Examples of the constitution having different nitrogen concentrations will hereinafter be described.

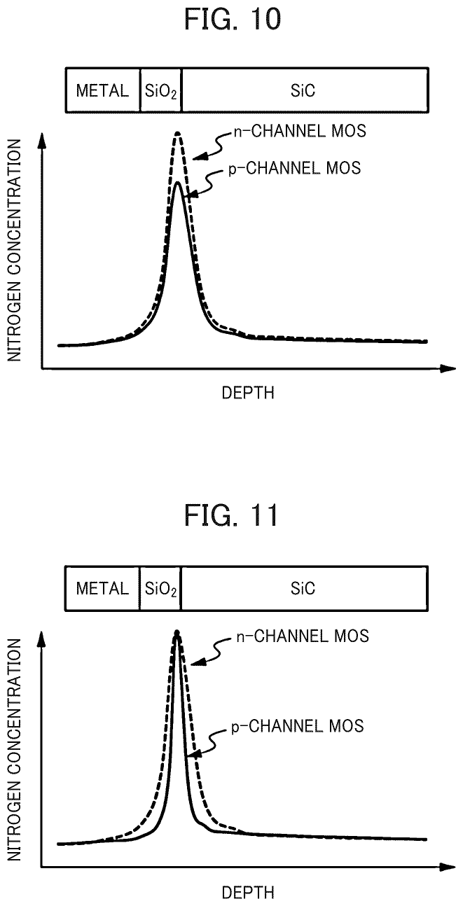

One example of the nitrogen concentration distribution in the depth direction of the n-channel MOS transistor 101 and the p-channel MOS transistor 102 in the present embodiment is shown in FIG. 10.

In the nitrogen concentration distribution shown in FIG. 10, the maximum nitrogen concentration (peak in the distribution in the depth direction) is made smaller in the p-channel MOS transistor 102 than in the n-channel MOS transistor 101.

Next, another example of the nitrogen concentration distribution in the depth direction of the n-channel MOS transistor 101 and the p-channel MOS transistor 102 in the present embodiment is shown in FIG. 11.

In the nitrogen concentration distribution shown in FIG. 11, the integration value of the nitrogen concentration (width in the distribution in the depth direction) is made smaller in the p-channel MOS transistor 102 than in the n-channel MOS transistor 101.

The integration value of the nitrogen concentration is difficult to measure directly, but it is proportional to the nitrogen introduction amount.

Therefore, the integration value of the nitrogen concentration can be made smaller by making the nitrogen introduction amount of the p-channel MOS transistor 102 smaller than that of the n-channel MOS transistor 101.

Examples of the specific step for making the nitrogen concentration smaller as described above may include decreasing the nitriding temperature, decreasing the nitriding time, and use of them in combination.

### Second Embodiment

A semiconductor device of Second Embodiment of the present invention will next be described.

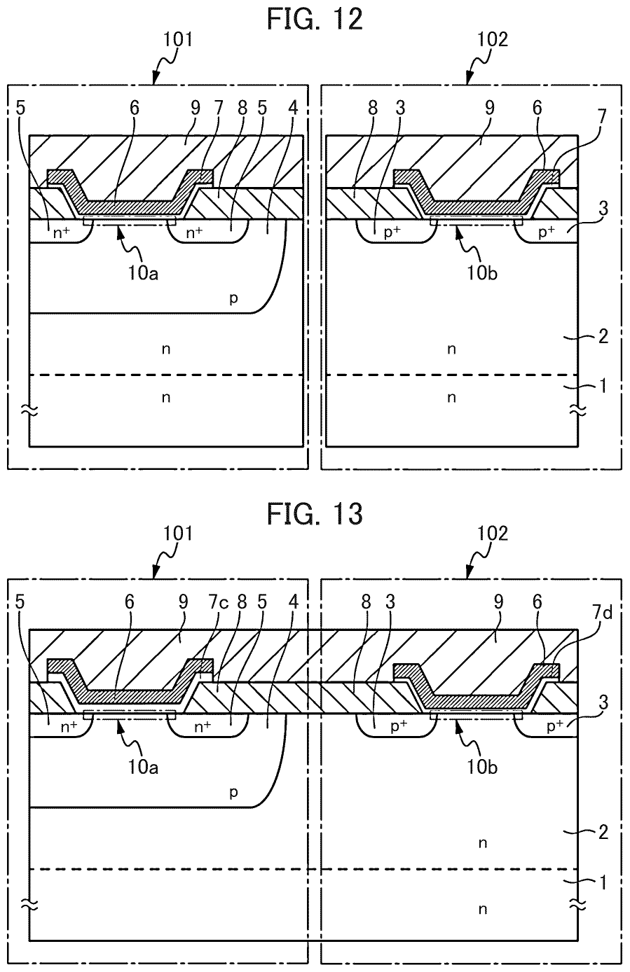

The schematic block view (cross-sectional view) of the semiconductor device of Second Embodiment of the present invention is shown in FIG. 12.

In the semiconductor device shown in FIG. 12, the n-channel MOS transistor 101 and the p-channel MOS transistor 102 are on the respectively different SiC substrates 1.

The semiconductor device shown in FIG. 12 also has a constitution in which the nitrogen concentration of the region 10b of the p-channel MOS transistor 102 is smaller than that of the region 10a of the n-channel MOS transistor 101.

With respect to another constitution, the semiconductor device of the present embodiment is similar to that shown in FIG. 1 so that overlapping description is omitted.

Even if a semiconductor device has a constitution in which the n-channel MOS transistor 101 and the p-channel MOS transistor 102 are on the respectively different SiC substrates 1 as shown in FIG. 12, an effect similar to that available by the semiconductor device shown in FIG. 1 can be obtained by applying the present invention to it.

In other words, by adopting a constitution in which the nitrogen concentration of the region 10b of the p-channel MOS transistor 102 is made smaller than that of the region 10a of the n-channel MOS transistor 101, NBTI can be suppressed and the offset drift of the SiC amplifier can be reduced.

In addition, the unsteadiness in the output of the amplifier at DC (direct current) can be reduced.

Particularly, in the semiconductor device of the present embodiment shown in FIG. 12, the n-channel MOS transistor 101 and the p-channel MOS transistor 102 are on the respectively different SiC substrates 1. Therefore, when the semiconductor device shown in FIG. 12 is manufactured, it is also possible to separately manufacture the n-channel MOS transistor 101 and the p-channel MOS transistor 102 in advance, connecting them to each other, and thereby completing the semiconductor device shown in FIG. 12. By using such a method, the number of the formation times of a resist or the like to be used as a mask can be reduced. In other words, in FIGS. 2 to 7 showing the manufacturing method of First Embodiment, five resists 21 to 25 are formed. When the semiconductor device of the present embodiment is manufactured, on the other hand, some (21, 23, and 24, or 22 and 25) of the five resists 21 to 25 may be formed in each of the transistors 101 and 102.

### Third Embodiment

The semiconductor device of Third Embodiment of the present invention will next be described.

The schematic block diagram (cross-sectional view) of Third Embodiment of the present invention is shown in FIG. 13.

In the semiconductor device shown in FIG. 13, the thickness of a gate oxide film 7d of the p-channel MOS transistor 102 is made smaller than that of a gate oxide film 7c of the n-channel MOS transistor 101.

With respect to another constitution, the semiconductor device of the present embodiment is similar to that shown in FIG. 1 so that overlapping description is omitted.

In the semiconductor device shown in FIG. 13, the thickness of the gate oxide film 7d of the p-channel MOS transistor 102 is made smaller than that of the gate oxide film 7c of the n-channel MOS transistor 101. This constitution also can suppress NBTI and reduce the offset drift of the SiC amplifier. In addition, the unsteadiness in the output of the amplifier at DC (direct current) can be reduced.

By using, in combination, the constitution in which the nitrogen concentration of the region 10b of the p-channel MOS transistor 102 is smaller than that of the region 10a of the n-channel MOS transistor 101 and the constitution which is specific to the present embodiment and in which the thickness of the gate oxide film 7d of the p-channel MOS transistor 102 is smaller than that of the gate oxide film 7c of the n-channel MOS transistor 101, it is possible to enhance the effects of suppressing NBTI, reducing the offset drift of the SiC amplifier, and reducing the unsteadiness of the output of the amplifier at DC (direct current).

### Fourth Embodiment

An integrated circuit according to Fourth Embodiment of the present invention will next be described.

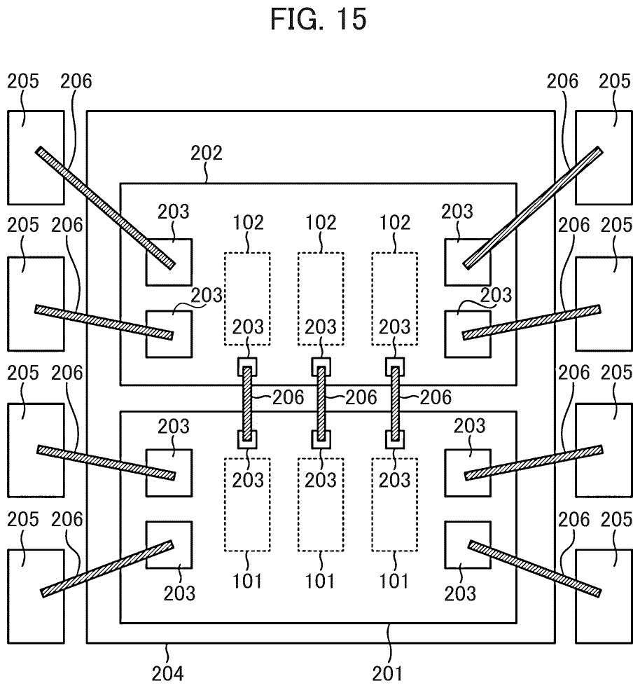

The schematic block diagram (plan view) of the integrated circuit of Fourth Embodiment of the present invention is shown in FIG. 15.

The integrated circuit of the present embodiment shown in FIG. 15 is similar to that of Second Embodiment shown in FIG. 12 in the respect that the n-channel MOS transistor 101 and the p-channel MOS transistor 102 are on respectively different substrates.

The integrated circuit of the present embodiment has three n-channel MOS transistors 101 and three p-channel MOS transistors 102.

The three n-channel MOS transistors 101 are formed on a first chip 201 and the three p-channel MOS transistors 102 are formed on a second chip 202.

The first chip 201 and the second chip 202 are formed on a die pad 204.

The first chip 201 and the second chip 202 each have thereon seven electrode pads 203. Of the seven electrode pads 203, four electrode pads 203 provided at the right end portion or left end portion are connected, via a metal wire 206, to a terminal 205 provided outside the chip. Of the seven electrode pads 203, two electrode pads 203 provided at an end portion on the side of the adjacent chip is connected, via a metal wire 206, to the electrode pad 203 of the adjacent chip.

Although not shown in the diagram, the three n-channel MOS transistors 101 and the three p-channel MOS transistors 102 each have a gate electrode on the main surface of the substrate of the chips 201 and 202 via a gate oxide film, and at the same time, have a dangling bond terminated by the addition of nitrogen at the interface between the substrate and the gate oxide film.

Further, the integrated circuit of the present embodiment has a constitution in which the concentration of nitrogen with which a dangling bond is terminated in the three p-channel MOS transistors 102 is smaller than that of nitrogen with which a dangling bond is terminated in the three n-channel MOS transistors.

According to the integrated circuit of the present embodiment, the concentration of nitrogen with which a dangling bond is terminated in the three p-channel MOS transistors 102 is smaller than that of nitrogen with which a dangling bond is terminated in the three n-channel MOS transistors.

Similar to the semiconductor device of First Embodiment shown in FIG. 1 or the semiconductor device of Second Embodiment shown in FIG. 12, the semiconductor device of the present embodiment can suppress NBTI and reduce the offset drift of the SiC amplifier. In addition, the unsteadiness in the output of the amplifier at DC (direct current) can be reduced.

In addition, according to the integrated circuit of the present embodiment, the three n-channel MOS transistors 101 are formed on the first chip 201 and the three p-channel MOS transistors 102 are formed on the second chip 202.

Since three n-channel MOS transistors 101 are formed on the same first chip 201, these three n-channel MOS transistors 101 can be made similar in properties such as threshold voltage.

Since three p-channel MOS transistors 102 are formed on the same second chip 202, these three p-channel MOS transistors 102 can be made similar in properties such as threshold voltage.

The characteristics of the integrated circuit can thus be stabilized because the characteristics of the three n-channel MOS transistors 101 or those of the three p-channel MOS transistors 102 can be made similar as described above.

In the integrated circuit shown in FIG. 15, seven electrode pads 203 and three MOS transistors 101 or 102 are formed on the first chip 201 or the second chip 202, but the number of the electrode pads or the MOS transistors to be provided on each chip is not limited to the aforesaid number but they may be changed to another one.

### Fifth Embodiment

An integrated circuit of Fifth Embodiment of the present invention will next be described.

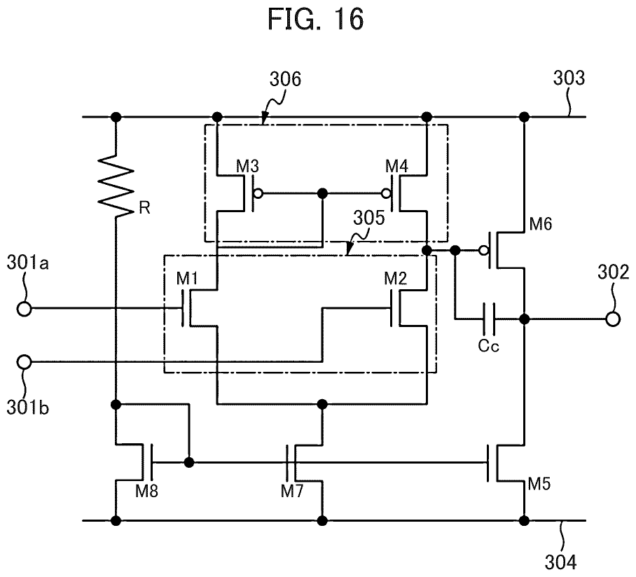

The schematic block diagram (circuit view) of the integrated circuit of Fifth Embodiment of the present invention is shown in FIG. 16.

The integrated circuit of the present embodiment shown in FIG. 16 has input terminals 301a and 301b, an output terminal 302, a power supply line 303 on a high voltage side, a power supply line 304 on a low voltage side, a phase compensation capacitor Cc, n-channel MOS transistors M1 and M2, p-channel MOS transistors M3 and M4, a resistor R, and MOS transistors M5, M6, M7, and M8.

The input terminal 301a is connected to the gate of the n-channel MOS transistor M1.

The input terminal 301b is connected to the gate of the n-channel MOS transistor M2.

The output terminal 302 is connected to one of the source and drain of the n-channel MOS transistor M2 via the phase compensation capacitor Cc.

One of the source and drain of the n-channel MOS transistors M1 and M2 is connected to the MOS transistor M7. The other one of the source and drain of the n-channel MOS transistors M1 and M2 is connected to one of the source and drain of the p-channel MOS transistors M3 and M4 which are adjacent to each other, respectively.

The other one of the source and drain of the p-channel MOS transistors M3 and M4 is connected to the power supply line 303 on a high voltage side.

The other one of the source and drain of the n-channel MOS transistor M1 and one of the source and drain of the p-channel MOS transistor M3 are connected to the gates of the p-channel MOS transistors M3 and M4.

The other one of the source and drain of the n-channel MOS transistor M2 and one of the source and drain of the p-channel MOS transistor M4 are connected to the gate of the MOS transistor M6 and one of the electrodes of the phase compensation capacitor Cc.

The other electrode of the phase compensation capacitor Cc is connected to the output terminal 302, the other one of the source and drain of the MOS transistor M5, and one of the source and drain of the MOS transistor M6.

One of the source and drain of each of the MOS transistors M5, M7, and M8 is connected to the power supply line 304 on the low voltage side.

The other one of the source and drain of the MOS transistor M6 is connected to the power supply line 303 on the high voltage side.

The other one of the source and drain of the MOS transistor M8 is connected to the power supply line 303 on the high voltage side via the resistor R. The other one of the source and drain of the MOS transistor M8 is connected also to the gate of the MOS transistor M8.

In the integrated circuit shown in FIG. 16, a differential circuit (SiC amplifier) is constituted of the input terminals 301a and 301b, the output terminal 302, the n-channel MOS transistors M1 and M2, the power supply line 303 on the high voltage side, the power supply line 304 on the low voltage side, the phase compensation capacitor Cc, and the like.

This differential circuit can amplify a difference between a signal to be input into the input terminal 301a and a signal to be input into the input terminal 301b and output it from the output terminal 302.

The integrated circuit of the present embodiment has a constitution in which the concentration of nitrogen with which a dangling bond in the two p-channel MOS transistors M3 and M4 is terminated is smaller than the concentration of nitrogen with which a dangling bond in the two n-channel MOS transistors M1 and M2 is terminated.

This makes it possible to suppress NBTI and reduce the offset drift of the SiC amplifier. In addition, the unsteadiness in the output of the amplifier at DC (direct current) can be reduced.

Particularly in the integrated circuit of the present embodiment, two n-channel MOS transistors M1 and M2 in a region 305 are formed on at least the same chip. Two p-channel MOS transistors M3 and M4 in a region 306 are formed on at least the same chip, too.

The chip formed in the region 305 (n channel MOS transistors M1 and M2) and the chip formed in the region 306 (p-channel MOS transistors M3 and M4) may be the same chip or respectively different chips.

Particularly in the integrated circuit shown in FIG. 16, the differential circuit is formed on the same chip as that on which the region 305 (two n-channel MOS transistors M1 and M2) is formed.

This constitution, in addition to the aforesaid constitution in which the nitrogen concentration is small, can suppress the offset drift of the differential circuit (siC amplifier).

By forming, on the same chip, the two p-channel MOS transistors M3 and M4 in the region 306, the two p-channel MOS transistors M3 and M4 can have similar properties.

This makes it possible to largely reduce a difference in threshold voltage between two p-channel MOS transistors M3 and M4 compared with that of a constitution in which the two transistors are formed on the respectively different chips, whereby the integrated circuit can have stable characteristics.

In the constitution shown in FIG. 16, the differential circuit is formed on the same chip as that having thereon the n-channel MOS transistors M1 and M2, but the constitution of the integrated circuit of the present invention is not limited to such one.

The constitution may be that having a differential circuit on a chip having thereon a p-channel MOS transistor or that having a differential circuit on a chip having thereon both the n-channel MOS transistor and p-channel MOS transistor.

The constitution is not limited to that having a differential circuit on the same chip as that having the MOS transistor thereon, but also may be that having a portion of a differential circuit on the same chip as that having thereon the MOS transistor.

### Sixth Embodiment

An integrated circuit of Sixth Embodiment of the present invention will next be described.

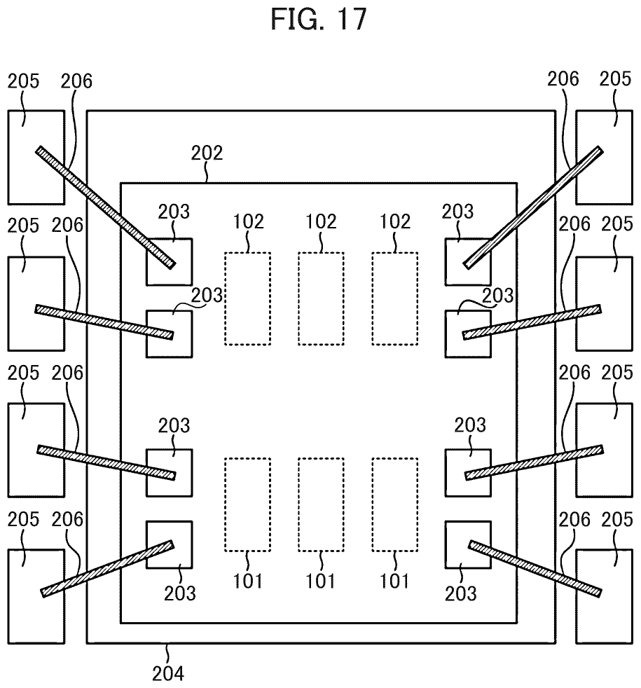

The schematic block diagram (plan view) of the integrated circuit of Sixth Embodiment of the present invention is shown in FIG. 17.

The integrated circuit of the present embodiment shown in FIG. 17 is similar to the semiconductor device of First Embodiment shown in FIG. 1 in the respect that the n-channel MOS transistor 101 and the p-channel MOS transistor 102 are on the same substrate.

The integrated circuit of the present embodiment has three n-channel MOS transistors 101 and three p-channel MOS transistors 102 and these three n-channel MOS transistors 101 and three p-channel MOS transistors 102 are all on one chip 207. The chip 207 is on a die pad 204.

The chip 207 has eight electrode pads 203. Of these eight electrode pads 203, four pads are provided on the right end portion or left end portion of the chip 207 and they are connected, via a metal wire 206, to a terminal 205 provided outside the chip.

Although not shown in the diagram, the three n-channel MOS transistors 101 and the three p-channel MOS transistors 102 each have a gate electrode on the main surface of the substrate of the chip 207 via a gate oxide film and at the same time, have a dangling bond terminated by the addition of nitrogen at the interface between the substrate and the gate oxide film.

Further, the integrated circuit of the present embodiment has a constitution in which the concentration of nitrogen with which a dangling bond is terminated in the three p-channel MOS transistors 102 is smaller than that of nitrogen with which a dangling bond is terminated in the three n-channel MOS transistors.

Another constitution is similar to that of the integrated circuit shown in FIG. 15 so that an overlapping description is omitted.

According to the integrated circuit of the present embodiment, the concentration of nitrogen with which a dangling bond is terminated in the three p-channel MOS transistors 102 is smaller than that of nitrogen with which a dangling bond is terminated in the three n-channel MOS transistors.

Similar to the semiconductor device of First Embodiment shown in FIG. 1 or the semiconductor device of Second Embodiment shown in FIG. 12, the semiconductor device of the present embodiment can suppress NBTI and reduce the offset drift of the SiC amplifier. In addition, the unsteadiness in the output of the amplifier at DC (direct current) can be reduced.

According to the integrated circuit of the present embodiment, the three n-channel MOS transistors 101 and the three p-channel MOS transistors 102 are formed on the same chip 207.

Since the three n-channel MOS transistors 101 are formed on the same chip 207, these three n-channel MOS transistors 101 can be made similar in properties such as threshold voltage.

Since the three p-channel MOS transistors 102 are formed on the same chip 207, these three p-channel MOS transistors 102 can be made similar in properties such as threshold voltage.

The characteristics of the integrated circuit can thus be stabilized because the characteristics of the three n-channel MOS transistors 101 or those of the three p-channel MOS transistors 102 can be made similar as described above.

In the integrated circuit of the present embodiment, three n-channel MOS transistors 101 and three p-channel MOS transistors 102 are each on one chip 207.

In this integrated circuit, the manufacturing steps of the chip 207 are more complicated than those of the integrated circuit shown in FIG. 15, but the constitution for connecting between substrates becomes unnecessary, making it possible to reduce the number of the electrode pads 203 and metal wires 206 and thereby increase the degree of freedom in designing of the layout of the integrated circuit.

The die pad 204 in FIG. 17 has the same area as that in FIG. 15, but due to the increased degree of freedom in designing of the layout, the distance between the n-channel MOS transistor 101 and the p-channel MOS transistor 102 can be made narrower than that shown in FIG. 17. By narrowing the distance as described above, the respective areas of the chip 207 and the die pad 204 can be decreased and an integrated circuit having a smaller size can be manufactured.

The integrated circuit shown in FIG. 17 has eight electrode pads 203, three n-channel MOS transistors 101, and three p-channel MOS transistors 102 on the chip 207.

The number of the electrode pads and the number of the MOS transistors, each provided on the chip, are not limited to these numbers and any other number may be possible.

### Modification Example

In the description of each of the aforesaid embodiments, an element with which a dangling bond is terminated at the interface between the substrate of the MOS transistors 101 and 102 and the gate oxide film is nitrogen.

The element with which a dangling bond is terminated is not limited to nitrogen, but another element such as hydrogen or phosphorus may be used.

The present invention is not limited to the constitutions described above in the embodiments and examples and various changes may be made without departing from the technical scope of the present invention. A portion or all of the constitutions described above in the examples may be used in combination.

What is claimed is:

1. A semiconductor device, comprising:
an n-channel MOS transistor formed on a main surface of a substrate using silicon carbide, and
a p-channel MOS transistor formed on a main surface of a substrate using silicon carbide, wherein:
each of the n-channel MOS transistor and the p-channel MOS transistor has, on the main surface of the substrate, a gate electrode via a gate oxide film, and a dangling bond is terminated, at an interface between the substrate and the gate oxide film, by an element added, and
a concentration of the element with which the dangling bond is terminated in the p-channel MOS transistor is smaller than that with which the dangling bond is terminated in the n-channel MOS transistor.

2. The semiconductor device according to claim 1, wherein
the element is nitrogen, and
the concentration of nitrogen in the p-channel MOS transistor is smaller than that in the n-channel MOS transistor.

3. The semiconductor device according to claim 1, wherein
a maximum concentration in a concentration distribution of the element is smaller in the p-channel MOS transistor than in the n-channel MOS transistor.

4. The semiconductor device according to claim 1, wherein
an integration value of a concentration in a concentration distribution of the element is smaller in the p-channel MOS transistor than in the n-channel MOS transistor.

5. The semiconductor device according to claim 1, wherein
the gate oxide film of the p-channel MOS transistor is thinner than the gate oxide film of the n-channel MOS transistor.

6. The semiconductor device according to claim 1, wherein
the n-channel MOS transistor and the p-channel MOS transistor are on the same substrate.

7. The semiconductor device according to claim 1, wherein
the n-channel MOS transistor and the p-channel MOS transistor are on respectively different substrates.

8. An integrated circuit provided with a semiconductor device comprising: a plurality of n-channel MOS transistors formed on a main surface of a substrate using silicon carbide; and a plurality of p-channel MOS transistors formed on a main surface of a substrate using silicon carbide, wherein
the integrated circuit has the plurality of n-channel MOS transistors and the plurality of p-channel MOS transistors,
the plurality of n-channel MOS transistors and the plurality of p-channel MOS transistors each have, on the main surface of the substrate, a gate electrode via a gate oxide film and at the same time, at the interface between the substrate and the gate oxide film, a dangling bond is terminated with nitrogen added, and
a concentration of the element with which the dangling bond is terminated in the plurality of p-channel MOS transistors is smaller than that of the element with which the dangling bond is terminated in the plurality of n-channel MOS transistors.

9. The integrated circuit according to claim 8, wherein
the plurality of n-channel MOS transistors are formed on a first substrate, and the plurality of p-channel MOS transistors are formed on a second substrate different from the first substrate.

10. The integrated circuit according to claim 8, further comprising a differential circuit, wherein
the differential circuit or a portion of the differential circuit is formed on the same substrate as that of the plurality of n-channel MOS transistors and/or the plurality of p-channel MOS transistors.

11. The integrated circuit according to claim 8, wherein
the plurality of n-channel MOS transistors and the plurality of p-channel MOS transistors are formed on the same substrate.
